(19) United States
(12) Patent Application Publication
(10) Pub. No.: US 2026/0100213 A1
(43) Pub. Date: Apr. 9, 2026

(54) DUAL-PORT MEMORY CIRCUIT COMPRISING FERAM CELLS

(71) Applicant: Commissariat à l'Energie Atomique et aux Energies Alternatives, Paris (FR)

(72) Inventors: Jean-Philippe NOEL, Grenoble (FR); Bastien GIRAUD, Grenoble (FR)

(21) Appl. No.: 19/347,546

(22) Filed: Oct. 1, 2025

(30) Foreign Application Priority Data
Oct. 4, 2024 (FR) 2410751

(51) Int. Cl. G11C 11/22

(52) U.S. Cl. CPC G11C 11/2273; G11C 11/2275

(57) ABSTRACT

A dual-access memory circuit (100), comprising FeRAM cells (102) arranged in rows and columns, each coupled to plate lines (106) and bit lines (112A, 112B) common to a column; and, during a dual access to cells (102.1-102.4) belonging to different columns, the memory circuit is configured to apply, to bit lines coupled to access transistors of unselected memory cells and set to the on state, electrical potentials of the same values as those applied to the plate lines coupled to the memory elements of the unselected memory cells.

### FIELD

This description generally concerns the field of memory circuits, or memory devices, with dual-port FeRAM cells adapted to implement a dual read and/or write access.

### BACKGROUND

The multi-banking design of a memory circuit consists of segmenting the address space of the memory into several distinct banks. These memory banks often have identical capacities to facilitate their design and programming. This memory architecture has the advantage of reducing memory latency while increasing its energy efficiency. However, in the case of a memory circuit with simultaneous multiple (two or more) accesses, this architecture does not allow multiple accesses within a same bank and therefore, restricts the flexibility of memory space partitioning to a granularity corresponding to that of the memory circuit banks. In this case, it is therefore necessary to know the memory architecture in order to optimize the distribution of the code and/or data to be manipulated and prevent simultaneous addressing conflicts.

Another possible design is that of dual-port memories that allows simultaneous dual access to any area of the address space of a memory, without restricting multiple accesses to a same bank, i.e. parallel accesses to two different memory cells. This design also has the advantage that it is not necessary to know the internal architecture of the memory in order to program it. It also allows for a better scalability of the memory space partitioning during the life of the memory, particularly between data regions and code or instruction regions. On the other hand, this memory architecture may require enlarging the surface area occupied by each memory cell in order to add the additional access port compared to single-port memory cells. It also requires the addition of an address decoder and additional read/write inputs/outputs to manage this second port, thus impacting the total surface area occupied by the memory.

A dual-port DRAM memory cell can be of the 2T1C type, i.e. comprising two access transistors coupled to a storage capacitor. The gates of the two access transistors are coupled to distinct word lines, one of the source/drain electrodes of each access transistor is coupled to the storage capacity, while the other is coupled to a bit line specific to each of the access transistors. The access transistors are identical in size. However, a DRAM memory cell, whether single-port or dual-port, has the disadvantage of being volatile. Current leakage in such a cell requires to carry out a periodic refreshing of the data stored in the cell.

A dual-port FeRAM memory cell has a similar architecture to that of a dual-port DRAM memory cell, but with a variable polarization memory element containing a ferroelectric material that makes this type of memory cell non-volatile. Unlike a DRAM memory cell, a FeRAM memory cell does not therefore require the data stored in the cell to be refreshed. In this type of memory cell, a first electrode of the memory element is coupled to the access transistors and a second electrode of the memory element is coupled to a plate line to which an electrical potential is applied the value of which depends on the operation performed.

When reading a FeRAM memory cell, the bit line is precharged to a low state, or ‘0’ state, then its potential is left floating, while the potential of the plate line changes from the low state to a high state, or ‘1’ state. This corresponds to the application of a pulse to the plate line. The capacitive coupling of the cell's memory element will then generate on the bit line a voltage the magnitude of which varies depending on whether the ‘1’ or ‘0’ state is stored in this memory element. When writing a ‘0’ state to such a cell, a ‘0’ state potential is applied to the bit line and the potential applied to the plate line is in the ‘1’ state. Writing a ‘1’ state to the cell corresponds to a reverse bias compared to that of writing a ‘0’ state: the potential applied to the bit line is in the ‘1’ state and that applied to the plate line is in the ‘0’ state.

Reading a FeRAM memory cell, like reading a DRAM memory cell, is destructive, meaning that the stored data is erased when it is read. It is therefore necessary to implement a “write back” step, i.e. rewriting the data read, when reading a ‘1’ state. This rewriting in the memory cell is implemented immediately after it is read.

When the memory operates in a sequential access mode, to perform read or write operations in memory cells with consecutive addresses (as opposed to a random access), the access time to the memory cells to perform these read or write operations can be advantageously reduced compared to a random access to these same memory cells, because the word line(s) coupled to these memory cells do(es) not have to be deactivated and reactivated between successive read or write operations, particularly during burst accesses. Furthermore, it is not necessary to perform address decoding to determine in which memory cells the read or write operations are to be performed. The sequential accesses operation of the memory also has the advantage of being more robust to side-channel attacks that the memory may be subject to since this operation eliminates current inrushes due to the activation and deactivation of word lines and certain address decoding blocks.

However, during multiple accesses to FeRAM memory cells, address conflicts can occur when word lines associated with different rows of memory cells are activated at the same time. Memory cells that are not selected but are connected to these activated word lines may have one of their access transistors disturbed because their voltage V_{GS} becomes greater than their threshold voltage Vₜ and their voltage V_{DS} becomes greater than the difference (V_{GS}−Vₜ), which may cause an undesired change in the values stored in these memory cells that are not selected but at least one access transistor of which is turned on.

### SUMMARY

There is a need to provide a dual-access memory circuit that does not have the disadvantages described above and that comprises, in particular, dual-port memory cells that can simultaneously access two memory cells while preventing address conflicts.

To this end, one embodiment provides a dual-access memory circuit comprising at least:
memory cells of the FeRAM type arranged in rows and columns, each memory cell comprising at least one memory element a first electrode of which is coupled to a plate line common to a column of memory cells, and at least one first and one second access transistors each coupled to one of first and second bit lines common to said column of memory cells and having a gate coupled to one of first and second word lines common to a row of memory cells;
sense amplifiers and write drive circuits;
interconnection circuits each configured to couple the first and second bit lines and the plate lines of a group of columns of memory cells to one of the write drive circuits and to at least one of the sense amplifiers;
   wherein the memory circuit is configured to apply, during a dual read and/or write access to first and second memory cells belonging to different groups of columns of memory cells:
when the first and second memory cells belong to a same row of memory cells, electrical potentials of the same values on the first and second bit lines coupled to the access transistors of the other memory cells of the groups of columns of memory cells to which the first and second memory cells belong, or
when the first and second memory cells belong to different rows of memory cells, and on the bit lines coupled to the access transistors set to the on state of the other memory cells belonging to the same rows and columns of memory cells as the first and second memory cells, electrical potentials of the same values as those applied to the plate lines coupled to the memory elements of the first and second memory cells.

According to another embodiment, a dual-access memory circuit is provided, comprising at least:
memory cells of the FeRAM type arranged in rows and columns, each memory cell comprising at least one memory element a first electrode of which is coupled to a plate line common to a column of memory cells, and at least one first and one second access transistors each coupled to one of first and second bit lines common to said column of memory cells and having a gate coupled to one of first and second word lines common to a row of memory cells;
sense amplifiers and write drive circuits;
interconnection circuits each configured to couple the first and second bit lines and the plate lines of at least one column of memory cells to one of the write drive circuits and to at least one of the sense amplifiers;
   wherein, during a dual read and/or write access to first and second selected memory cells belonging to different columns of memory cells and different rows of memory cells, the memory circuit is configured to apply, to bit lines coupled to access transistors set to the on state and of other memory cells belonging to the same columns of memory cells than the first and second selected memory cells, electrical potentials of the same values as those applied to the plate lines coupled to the memory elements of the first and second selected memory cells, and
   wherein, during a dual read and/or write access to first and second selected memory cells, the memory circuit is configured to apply, to the bit lines coupled to the access transistors set in the on state and of unselected memory cells belonging to columns other than those to which the first and second selected memory cells belong, electrical potentials of the same values as those applied to the plate lines coupled to the memory elements of these unselected memory cells.

According to a particular embodiment, the interconnection circuits are each configured to couple the first and second bit lines and the plate lines of a group of memory cell columns to a shared write driver circuit and to a single shared sense amplifier or to two shared sense amplifiers connected respectively to the first and second bit lines of the group of columns.

According to a particular embodiment, the dual access is performed during sequential read and/or write accesses to at least a portion of the memory cells including the first and second memory cells.

According to a particular embodiment, the memory circuit is configured to apply, during sequential read and/or write accesses to memory cells belonging to at least one same row of memory cells, electrical potentials of constant values to the first and second word lines common to said at least one of the rows of memory cells, throughout the duration of said accesses so as to maintain in the on state, during the total duration of said accesses, the access transistors to which the first and second word lines are coupled, or at least one of the first and second word lines is coupled.

According to a particular embodiment, the memory circuit further comprises devices configured to divert charge from one of the first and second bit lines to the other in each of the columns of memory cells, or to divert charge from one of the first and second bit lines to a common bit line.

According to a particular embodiment, when the first and second memory cells belong to a same row of memory cells, the memory circuit is configured to turn on only one of the first and second access transistors of each of the first and second memory cells.

According to a particular embodiment, each of the interconnection circuits comprises first inputs coupled to the first bit lines of a group of columns of memory cells, second inputs coupled to the second bit lines of the group of columns of memory cells, third inputs coupled to the plate lines of the group of columns of memory cells, a first output configured to be coupled to at least one of the first inputs, a second output configured to be coupled to at least one of the second inputs and a third output configured to be coupled to at least one of the third inputs.

According to a particular embodiment:
during a read operation of one of the memory cells, the memory circuit is configured to apply to one of the first and second bit lines coupled to said memory cell an electrical potential corresponding to a first state, or a first state, and then a floating electrical potential, and to apply to the plate line coupled to said memory cell an electrical potential corresponding to a second state, or a second state, different from the first state;
during a write operation of the first state in one of the memory cells, the memory circuit is configured to apply an electrical potential corresponding to the first state, or the first state, to one of the first and second bit lines coupled to said memory cell and to apply an electrical potential corresponding to the second state, or the second state, to the plate line coupled to said memory cell;
during a write operation of the second state in one of the memory cells, the memory circuit is configured to apply an electrical potential corresponding to the second state, or the second state, to one of the first and second bit lines coupled to said memory cell and to apply an electrical potential corresponding to the first state, or the first state, to the plate line coupled to said memory cell.

According to a particular embodiment, the memory circuit is configured to apply, for each of the columns of memory cells, a same electrical potential to the first and second bit lines and the plate line of said column of memory cells during a precharge phase implemented at the beginning or end of a cycle of operations comprising a read operation.

According to a particular embodiment, the memory cells are configured to store words in the memory cells such that the bits of each word are stored in several groups of columns of memory cells.

According to a particular embodiment, each group of columns of memory cells is coupled to two sense amplifiers, and the memory circuit is configured to implement dual read access in first and second memory cells belonging to a same column of memory cells.

According to a particular embodiment, all interconnection circuits are controlled by a same control circuit.

According to a particular embodiment, the gate of each access transistor of each memory cell comprises a single electrically conductive portion.

According to a particular embodiment, the word lines comprise polysilicon portions extending in a start-of-line portion of an integrated circuit and metal portions extending in an end-of-line portion of the integrated circuit.

A method for making a dual-access memory circuit is also provided, comprising at least:
providing memory cells of the FeRAM type arranged in rows and columns, each memory cell comprising at least one memory element a first electrode of which is coupled to a plate line common to a column of memory cells, and at least one first and one second access transistors each coupled to one of first and second bit lines common to said column of memory cells and having a gate coupled to one of first and second word lines common to a row of memory cells;
providing sense amplifiers and write drive circuits;
providing interconnection circuits each configured to couple the first and second bit lines and the plate lines of a group of columns of memory cells to one of the write drive circuits and to at least one of the sense amplifiers;
   wherein the memory circuit is configured to apply, during a dual read or write access to first and second memory cells belonging to different groups of columns of memory cells:
when the first and second memory cells belong to a same row of memory cells, electrical potentials of the same values on the first and second bit lines coupled to the access transistors of the other memory cells of the groups of columns of memory cells to which the first and second memory cells belong, or
when the first and second memory cells belong to different rows of memory cells, electrical potentials of the same values as those applied to the plate lines coupled to the memory elements of the first and second memory cells on the bit lines coupled to the access transistors set to the on state of the other memory cells belonging to the same rows and columns of memory cells as the first and second memory cells.

A method for making a dual-access memory circuit is also provided, comprising at least:
providing memory cells of the FeRAM type arranged in rows and columns, each memory cell comprising at least one memory element a first electrode of which is coupled to a plate line common to a column of memory cells, and at least one first and one second access transistors, each coupled to one of first and second bit lines common to said column of memory cells and having a gate coupled to one of first and second word lines common to a row of memory cells;
providing sense amplifiers and write drive circuits;
providing interconnection circuits each configured to couple the first and second bit lines and the plate lines of at least one column of memory cells to one of the write drive circuits and to at least one of the sense amplifiers;
   wherein, during a dual read and/or write access to selected first and second memory cells belonging to different columns of memory cells and different rows of memory cells, the memory circuit is configured to apply, to bit lines coupled to access transistors set to the on state and of other memory cells belonging to the same columns of memory cells than the selected first and second memory cells, electrical potentials of the same values as those applied to the plate lines coupled to the memory elements of the selected first and second memory cells, and
   wherein, during a dual read and/or write access to first and second selected memory cells, the memory circuit is configured to apply, to the bit lines coupled to the access transistors set in the on state and of unselected memory cells belonging to columns other than those to which the first and second selected memory cells belong, electrical potentials of the same values as those applied to the plate lines coupled to the memory elements of these unselected memory cells.

According to a particular embodiment, the memory circuit is implemented in the form of an integrated circuit, and the method includes the implementation of polysilicon portions extending in a start-of-line portion of the integrated circuit and metal portions extending in an end-of-line portion of the integrated circuit, which together form the word lines.

A method for controlling memory cells of a memory circuit is also provided, comprising at least:
memory cells of the FeRAM type arranged in rows and columns, each memory cell comprising at least one memory element a first electrode of which is coupled to a plate line common to a column of memory cells, and at least one first and at least one second access transistors each coupled to one of first and second bit lines common to said column of memory cells and having a gate coupled to one of first and second word lines common to a row of memory cells;
sense amplifiers and write drive circuits;
interconnection circuits each configured to couple the first and second bit lines and the plate lines of a group of columns of memory cells to one of the write drive circuits and to at least one of the sense amplifiers;
   the method comprising applying, during a dual read and/or write access to first and second memory cells belonging to different groups of columns of memory cells:
when the first and second memory cells belong to a same row of memory cells, electrical potentials of the same values on the first and second bit lines coupled to the access transistors of the other memory cells of the groups of columns of memory cells to which the first and second memory cells belong, or
when the first and second memory cells belong to different rows of memory cells, electrical potentials of the same values as those applied to the plate lines coupled to the memory elements of the first and second memory cells on the bit lines coupled to the access transistors set to the on state of the other memory cells belonging to the same rows and columns of memory cells as the first and second memory cells.

A method for controlling memory cells in a memory circuit is also provided, comprising at least:
memory cells of the FeRAM type arranged in rows and columns, each memory cell comprising at least one memory element a first electrode of which is coupled to a plate line common to a column of memory cells, and at least one first and one second access transistors each coupled to one of first and second bit lines common to said column of memory cells and having a gate coupled to one of first and second word lines common to a row of memory cells;
sense amplifiers and write drive circuits;
interconnection circuits each configured to couple the first and second bit lines and the plate lines of at least one column of memory cells to one of the write drive circuits and to at least one of the sense amplifiers;
   and wherein, during a dual read and/or write access to first and second selected memory cells belonging to different columns of memory cells and different rows of memory cells, the method comprises applying, to bit lines coupled to access transistors set to the on state and of other memory cells belonging to the same columns of memory cells than the first and second selected memory cells, electrical potentials of the same values as those applied to the plate lines coupled to the memory elements of the first and second selected memory cells, and
   wherein, during a dual read and/or write access to first and second selected memory cells, the method comprises applying, to the bit lines coupled to the access transistors set in the on state and of unselected memory cells belonging to columns other than those to which the first and second selected memory cells belong, electrical potentials of the same values as those applied to the plate lines coupled to the memory elements of these unselected memory cells.

According to a particular embodiment, the method further comprises:
during a read operation of one of the memory cells, applying an electrical potential corresponding to a high state, or a high state, to one of the first and second word lines coupled to said memory cell, and applying, to one of the first and second bit lines coupled to said memory cell, an electrical potential corresponding to a low state, or a low state, and then a floating electrical potential, and applying, to the plate line coupled to said memory cell, an electrical potential changing from a low state to a high state, or a low state and then a high state;
during a write operation of a low state in one of the memory cells, applying an electrical potential corresponding to a high state, or a high state, to one of the first and second word lines coupled to said memory cell, and applying, to one of the first and second bit lines coupled to said memory cell, an electrical potential corresponding to a low state, or a low state, and applying, to the plate line coupled to said memory cell, an electrical potential corresponding to a high state, or a high state;
during a write operation of a high state in one of the memory cells, applying an electrical potential corresponding to a high state, or a high state, to one of the first and second word lines coupled to said memory cell, and applying, to one of the first and second bit lines coupled to said memory cell, an electrical potential corresponding to a high state, or a high state, and applying, to the plate line coupled to said memory cell, an electrical potential corresponding to a low state, or a low state.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 schematically illustrates memory cells of a memory circuit according to a particular embodiment;

FIG. 2 schematically illustrates a portion of a memory circuit according to a particular embodiment;

FIG. 3 schematically illustrates a portion of a memory circuit according to a particular embodiment;

FIG. 4 schematically illustrates bias signals applied to bit lines and plate lines during a sequential access to memory cells of a memory circuit according to a particular embodiment;

FIG. 5 schematically illustrates an exemplary design of an interconnection circuit present in a memory circuit according to a particular embodiment;

FIGS. 6 and 7 schematically illustrate exemplary designs of a sense amplifier present in a memory circuit according to a particular embodiment;

FIGS. 8, 9 and 10 schematically illustrate memory cells of a memory circuit according to a particular embodiment, in which operations are performed simultaneously in two memory cells of the memory circuit; and

FIG. 11 schematically illustrates a variant design of an interconnection circuit present in a memory circuit according to a particular embodiment.

### DETAILED DESCRIPTION OF THE PRESENT EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, various elements of the memory circuit (line decoder, control/drive circuit, registers, etc.) as well as the steps related to their implementation are not detailed. Those skilled in the art will be able to implement these elements in detail based on the functional description given here.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures in a normal position of use.

The terms “row” and “column” are also used in connection with an orientation corresponding to a normal position of use of the memory circuit, although this orientation may be different.

Unless specified otherwise, the expressions “about”, “approximately”, “substantially” and “in the order of” signify within 10%, and preferably within 5%.

A memory circuit 100 according to a particular embodiment is described below. The memory circuit 100 comprises at least one array of memory cells 102 of the FeRAM type. The memory cells 102 are arranged in rows and columns. According to an exemplary design, the memory circuit 100 may comprise between 16 and 1024 rows of memory cells 102 and between 16 and 1024 columns of memory cells 102.

In the memory circuit 100, a low state or ‘0’ state may correspond to an electrical potential equal to the reference electrical potential of the memory circuit 100, for example the electrical potential of the ground of the memory circuit 100. In addition, a high state or ‘1’ state may correspond to an electrical potential equal to the supply electrical potential of the memory circuit 100.

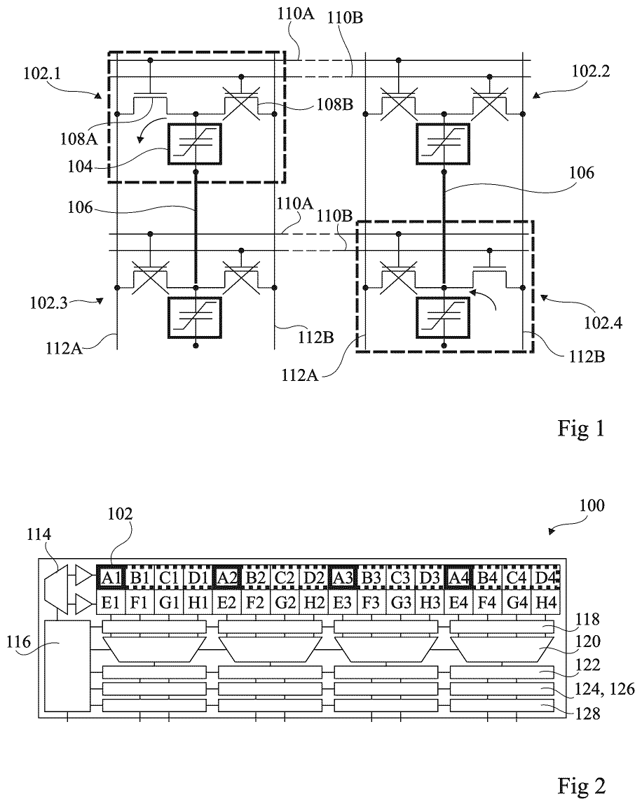

A portion of the array of memory cells 102 is shown in FIG. 1, this portion comprising here four memory cells 102 belonging to two distinct groups of columns of memory cells 102 and to two different rows (adjacent or not) of memory cells 102. In the example shown in FIG. 1, the four memory cells 102 shown are designated by references 102.1 to 102.4.

Each memory cell 102 comprises at least one memory element 104 of the FeRAM type, forming a non-volatile storage capacity. Each memory element 104 has a first of its electrodes coupled to a plate line 106 common to the memory cells 102 of a same column of memory cells 102. In the example shown in FIG. 1, a first plate line 106 is coupled to the memory elements 104 of the memory cells 102 of the column to which the memory cells 102.1 and 102.3 belong, and a second plate line 106 is coupled to the memory elements 104 of the memory cells 102 of the column to which the memory cells 102.2 and 102.4 belong.

The memory cells 102 correspond to dual-port memory cells. Each memory cell 102 comprises at least two access transistors 108A, 108B each coupled to one of two word lines 110A, 110B common to the memory cells 102 of a same row of memory cells 102 and to one of two bit lines 112A, 112B common to the memory cells 102 of a same column of memory cells 102. In the example shown in FIG. 1, in each memory cell 102, the memory element 104 has a second of its electrodes coupled to one of the source or drain electrodes of each of the access transistors 108A, 108B of the memory cell 102. In this particular example, in each memory cell 102, the other source or drain electrode of the access transistor 108A is coupled to a first of the two bit lines 112A associated with the column of memory cells 102 to which this memory cell 102 belongs, and the other source or drain electrode of the access transistor 108B is coupled to a second of the two bit lines 112B associated with the column of memory cells 102 to which this memory cell 102 belongs. Furthermore, in each memory cell 102, the gate of the access transistor 108A is coupled to a first of the two word lines 110A associated with the row of memory cells 102 to which this memory cell 102 belongs, and the gate of the access transistor 108B is coupled to a second of the two word lines 110B associated with the row of memory cells 102 to which this memory cell 102 belongs.

The memory cells 102 of the array are arranged in groups of columns of memory cells 102, called “data columns”, arranged next to each other parallel to the word lines 110A, 110B. Each group of columns of memory cells 102 comprises n columns of memory cells 102, with n being, for example, between 2 and 1024 (or even more in some cases), and generally equal to a number that is a power of 2. In addition, the array of memory cells 102 may comprise a number of groups of columns equal to the sum of the number of bits of the data bus of the memory circuit 100, which is, for example, 8, 16, 32 or 64, and of the number of check bits used to encode parity.

FIG. 2 schematically illustrates a portion of the memory circuit 100 according to a particular exemplary design. To facilitate understanding of the memory circuit 100, it is shown and described, in connection with FIG. 2, with a limited number of memory cells 102, the actual number of memory cells 102 in the memory circuit 100 being much greater than the number of memory cells 102 shown in FIG. 2.

In the example shown in FIG. 2, the memory cells 102 are arranged in the form of four groups of columns of memory cells 102, each comprising four columns of memory cells. Furthermore, only two rows of memory cells 102 are shown. In FIG. 2, the memory cells 102 of a first group of columns are designated by references “A1” to “H1,” the memory cells 102 of a second group of columns are designated by references “A2” to “H2,” the memory cells 102 of a third group of columns are designated by references “A3” to “H3” and the memory cells 102 of a fourth group of columns are designated by references “A4” to “H4.”

Arranging the memory cells 102 in several groups of columns arranged side by side parallel to the word lines 110 can be advantageous because it can provide, at the level of an integrated circuit forming the memory circuit 100, a shape well suited to the space and geometry constraints encountered for this type of circuit.

In a particular design, the memory circuit 100 is configured to store words in the array of memory cells 102 such that the bits of each word stored in the array of memory cells 102 are stored and distributed in different groups of columns of memory cells 102. In the example shown in FIG. 2, a first 4-bit word is to be stored in memory cells A1, A2, A3 and A4, a second 4-bit word is to be stored in memory cells B1 to B4, and so on, up to an eighth 4-bit word to be stored in memory cells H1 to H4.

In the exemplary design as described, the memory circuit 100 is configured to perform a dual read and/or write access simultaneously to different memory cells belonging to different groups of columns. In addition, the memory circuit 100 is configured here for operating, in at least one of its operating modes, in sequential access to the memory cells 102 column by column for the memory cells 102 of a same row, this access being repeated, for example, for each of the rows of memory cells 102 of the memory circuit 100.

In the exemplary design as described, the memory circuit 100 also comprises elements for managing accesses to word lines 110A and 110B. In the example as described, this management of accesses to word lines 110A and 110B is performed in particular by a line decoder 114 configured to apply electrical potentials to the word lines 110A and 110B in order to turn on access transistors 108A and 108B of row(s) of memory cells 102 during read and/or write operations in the desired memory cells 102.

In the example shown in FIG. 2, the memory circuit 100 further comprises a control circuit 116 configured to drive, in particular, the line decoder 114. In the example as described, during a sequential access to at least one row of memory cells 102, the line decoder 114 is configured to apply electrical potentials of constant values to the word lines 110A, 110B concerned by this sequential access throughout the duration of the access to the row or rows of memory cells 102. This makes it possible to maintain in the on state, during the total duration of said accesses, the access transistors 108A, 108B to which the first and second word lines 110A, 110B are coupled.

In the example shown in FIG. 2, the memory circuit 100 comprises one or more precharge circuits 118 coupled to the bit lines 112A, 112B and to the plate lines 106. In the example shown in FIG. 2, the memory circuit 100 includes several precharge circuits 118 each coupled to the bit lines 112A, 112B and to the plate lines 106 of one of the groups of columns of memory cells 102. The precharge circuit(s) 118 is or are configured in particular to apply precharge electrical potentials to the bit lines 112A, 112B and to the plate lines 106 between the read and/or write operations to be performed, and thus to have the desired electrical potentials on the bit lines 112A, 112B and on the plate lines 106 prior to the implementation of these operations.

The memory circuit 100 further comprises interconnection circuits 120. Each of the interconnection circuits 120 comprises first inputs/outputs coupled to the bit lines 112A, 112B and to the plate lines 106 of a group of columns of memory cells 102, as well as second inputs/outputs coupled to first and second common bit lines and to a common plate line. Each of the interconnection circuits 120 is configured to couple a plurality of first bit lines 112A to the first common bit line, a plurality of second bit lines 112B to the second common bit line and a plurality of plate lines 106 to the common plate line. In the example as described, each group of columns of memory cells 102 is coupled to an interconnection circuit 120 distinct from those to which the other group or groups of columns of memory cells 102 is or are coupled.

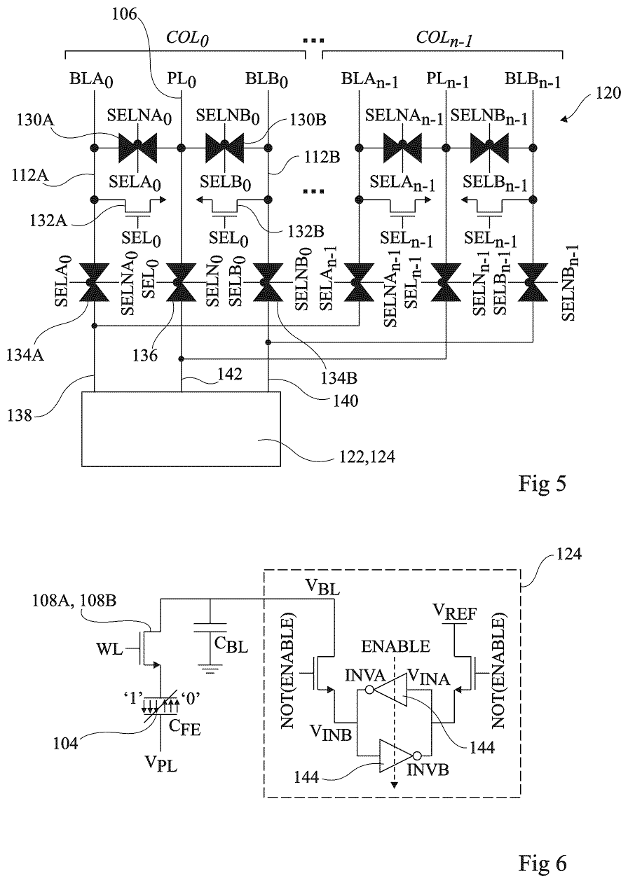

An exemplary design of such an interconnection circuit 120 is schematically illustrated in FIG. 5. In this example, the circuit 120 includes first transmission gates 130A, 130B, for example of the CMOS type, each connected between one of the bit lines 112A, 112B and the plate line 106 of each of the n columns (referred to as “COL₀” to “COLₙ₋₁” in FIG. 5) of the group of columns of memory cells 102 to which the interconnection circuit 120 is coupled. In this example, the interconnection circuit 120 also includes MOS transistors 132A, 132B each connected between one of the bit lines 112A, 112B and a reference electrical potential such as the ground. In this example, the interconnection circuit 120 also includes second transmission gates 134A each connected between one of the first bit lines 112A and a first common bit line 138, second transmission gates 134B each connected between one of the second bit lines 112B and a second common bit line 140 and second transmission gates 136 each connected between one of the plate lines 106 and a common plate line 142. The common bit lines 138, 140 and the common plate line 142 are coupled to at least one sense amplifier 124 and a write drive circuit 122 associated with this interconnection circuit 120. According to one embodiment, each common bit line 138, 140 is coupled to a different sense amplifier 124. According to another variant, these two common bit lines 138, 140 may be routed to the same shared sense amplifier. In the latter case of the shared sense amplifier, it is not possible to have two simultaneous readings of cells arranged on the same column or on the same group of columns sharing this single sense amplifier. Such simultaneous readings are possible in the opposite case, in the presence of different sense amplifiers 124.

In the exemplary design shown in FIG. 5, each of the first transmission gates 130A, 130B is used to couple one of the bit lines 112A, 112B to the plate line 106. Each of the MOS transistors 132A, 132B is used to couple one of the bit lines 112A, 112B to the reference electrical potential, for example during a precharge phase of the bit lines 112A, 112B. Each of the second transmission gates 134A, 134B, 136 is used to couple one of the bit lines 112A, 112B or one of the plate lines 106 to one of the common bit or plate lines 138, 140, 142.

Alternatively, the memory circuit 100 may include interconnection circuits 120 that are different from the example circuit 120 shown in FIG. 5.

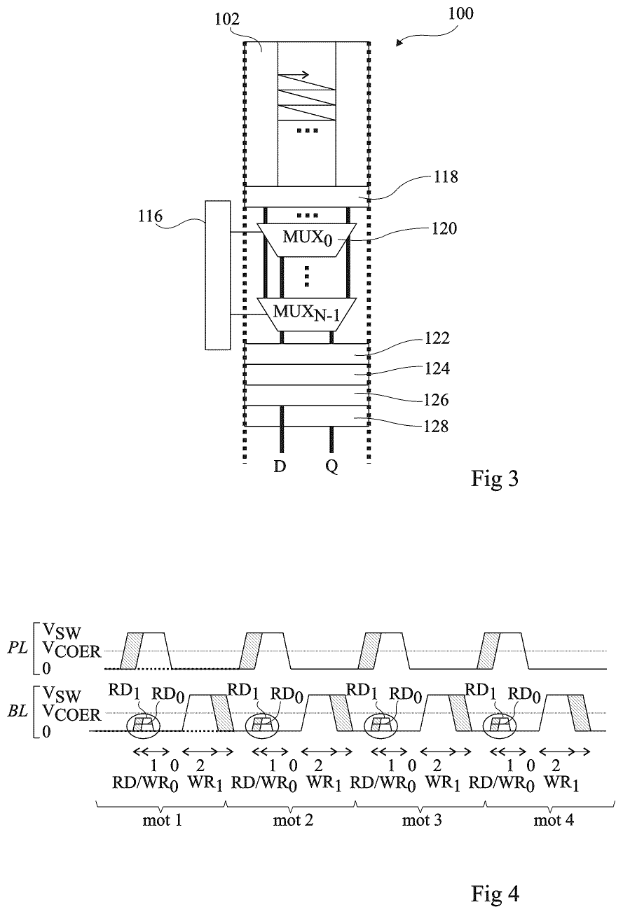

FIG. 3 shows in more detail components and circuits located at the bottom of one of the groups of columns of memory cells 102 of the memory circuit 100 according to the example as described.

In the example as described, all interconnection circuits 120 are controlled, or driven, by the control circuit 116. Furthermore, in the example shown in FIG. 3, the interconnection circuit 120 is shown in the form of n interconnected multiplexers.

In the example shown in FIGS. 2 and 3, the memory circuit 100 also includes write drive circuits 122 coupled to the common bit lines 138, 140 and to the common plate lines 142. These write drive circuits 122 allow the desired electrical potentials to be applied to the bit lines 112A, 112B and to the plate lines 106 via the interconnection circuits 120. In the example as described, each write drive circuit 122 is coupled to a group of columns of memory cells 102.

In the example shown in FIGS. 2 and 3, the memory circuit 100 comprises several sense amplifiers 124 each associated with the common bit lines 138, 140 of one of the groups of columns of memory cells 102.

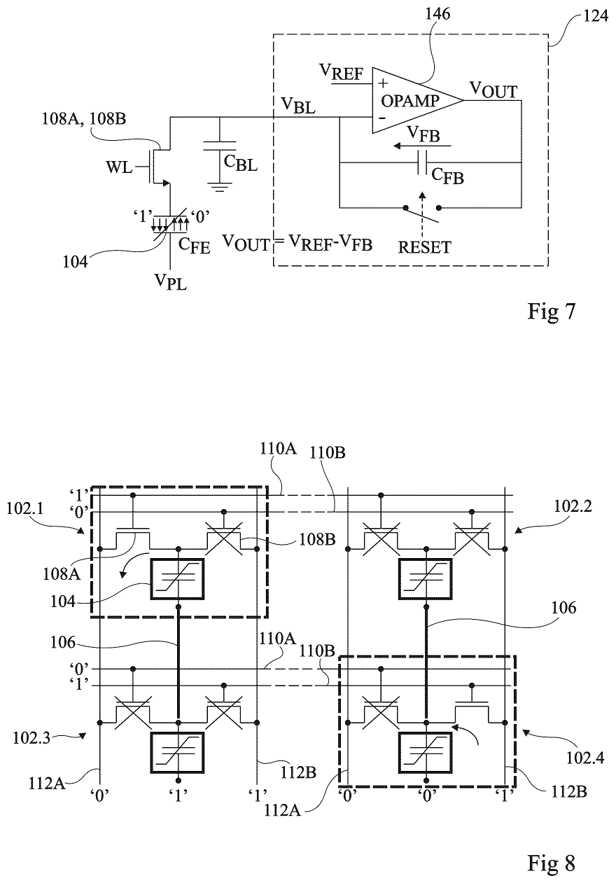

A first exemplary design of a sense amplifier 124 is shown in FIG. 6. In this example, the sense amplification is based on the use of two inverters 144 coupled head-to-tail with each other. A second exemplary design of a sense amplifier 124 is shown in FIG. 7. In this example, the implemented sense amplification is based on the use of an operational amplifier 146 mounted as an integrator. In both examples, a precharge is implemented, then a read current is read and amplified. The reads implemented in both examples empty the charge present in the storage element 104 being read. Details of the operation of the first and second examples of sense amplifier 124 shown above are described, for example, in the document by O. Billoint et al., “Charge-based Sense Demonstration in 1T-1C HZO FeRAM Arrays to Overcome CBL-induced Bank Size Limitations,” 2024 IEEE International Memory Workshop (IMW), Seoul, Korea, Republic of, 2024, pp. 1-4.

In the exemplary design described here, each group of columns of memory cells 102 is coupled to a sense amplifier 124. Coupling a single sense amplifier 124 to each group of columns of memory cells 102 allows simultaneous reading of two memory cells 102 located in different groups of columns. In another example, each group of columns of memory cells 102 may be coupled to two sense amplifiers 124, allowing two different memory cells 102 located in a same column of memory cells 102 to be read.

In the example shown in FIGS. 2 and 3, the memory circuit 100 also includes SIPO (Serial In/Parallel Out) registers 126. In the example shown in FIGS. 2 and 3, the memory circuit 100 includes several registers 126 each associated with the bit lines 112A, 112B of one of the groups of columns of memory cells 102 and each having a storage capacity of N bits when the groups of columns of memory cells 102 each include N columns of memory cells 102. The use of such SIPO registers 126 allows the memory circuit 100 to be compatible with systems operating at frequencies higher than that of the memory circuit 100, such as when the memory circuit 100 is used in a data logger where the write operations are much more numerous than the read operations.

In the example shown in FIGS. 2 and 3, the memory circuit 100 also includes D flip-flops 128 such that one or more D flip-flops 128 is or are associated with each group of columns of memory cells 102. The D flip-flops 128 allow the output data to be stored before it is retrieved and used.

When the memory circuit 100 performs a sequential access to a row of memory cells 102, the potential applied to one of the two word lines 110 of this row of memory cells 102 is in the ‘1’ state and that applied to the other word line 110 of this row of memory cells 102 is in the ‘0’ state. FIG. 4 schematically illustrates bias signals applied to bit lines 112A, 112B and to plate lines 106 during such sequential access. The PL signal is applied successively to plate lines 106 coupled to the memory cells 102 in which the read and/or write operations are performed, these plate lines 106 being physically distinct from one another so as to sequentially address words whose bits are arranged one after the other as shown in FIG. 2. Similarly, the BL signal is applied successively to one of the bit lines 112 (the one coupled to the access transistor 108 set to the on state) coupled to the memory cells 102 in which the read and/or write operations are performed.

In FIG. 4, the BL and PL signals correspond to the signals applied to access memory cells 102 in order to sequentially read or write four words in the array of memory cell 102. Depending on whether it is a read operation, a write operation of a ‘0’ state or a write operation of a ‘1’ state in one of the memory cells, the BL and PL signals differ. Setting one of the bit lines 112A, 112B or the plate lines 106 to the ‘0’ or ‘1’ state is achieved by connecting an active bias circuit to that bit line 112A, 112B or plate line 106 in order to apply a desired bias voltage value to that line. These bias circuits correspond, for example, to MOS transistors connecting the desired node to the reference electrical potential or to the supply electrical potential depending on a control signal emitted by the control circuit 116. This bias of the bit lines 112A, 112B and plate lines 106 differs from the high impedance state of these lines in which no active bias is applied.

In the example as described:
during a read operation of one of the memory cells 102, one of the first and second word lines 110A, 110B connected to this memory cell 102 is set to the ‘1’ state so as to turn on one of the access transistors 108A, 108B, the bit line 112A, 112B coupled to the access transistor 108A, 108B set to the on state of the memory cell 102 to be read is precharged to the ‘0’ state and then its potential is left floating, while the potential applied to the plate line 106 coupled to the memory cell 102 changes from the ‘0’ state to the ‘1’ state. The potential read on the bit line 112A, 112B coupled to the access transistor 108A, 108B set to the on state is then representative of the state stored in the memory cell 102;
during an operation to write a ‘0’ state in one of the memory cells 102, one of the word lines 110A, 110B connected to this memory cell 102 is set to the ‘1’ state so as to turn on one of the access transistors 108A, 108B, the potential applied to the bit line 112A, 112B coupled to the access transistor 108A, 108B set to the on state of the memory cell 102 is in the ‘0’ state while the potential applied to the plate line 106 coupled to the memory cell 102 is in the ‘1’ state;
during an operation to write a ‘1’ state in one of the memory cells 102, one of the word lines 110A, 110B connected to this memory cell 102 is set to the ‘1’ state so as to turn on one of the access transistors 108A, 108B, the potential applied to the bit line 112A, 112B coupled to the access transistor 108A, 108B set to the on state of the memory cell 102 is in the ‘1’ state while the potential applied to the plate line 106 coupled to the memory cell 102 is in the ‘0’ state.

The BL and PL signals shown in FIG. 4 correspond, during the access performed for each reading or writing of a word, to a first phase of reading or writing a ‘0’ state (phase 1 called “RD/WR0” in FIG. 4), followed by a second phase of writing a ‘1’ state (phase 2 called “WR1” in FIG. 4). When a read operation is performed, the ‘1’ state is only written if the read value corresponds to the ‘1’ state. In the case of writing a ‘0’ state, the value of the BL signal is maintained at the ‘0’ state for the duration of the pulse of the PL signal (phase 1), and no pulse in the ‘1’ state is then applied to the BL signal during the phase 2. In the case of writing a ‘1’ state, the value of the BL signal is maintained at the ‘0’ state for the duration of the pulse of the PL signal (phase 1), and a pulse changing from the ‘0’ state to the ‘1’ state is then applied to the BL signal during the phase 2. Regardless of the operation as performed, the sequence applied to the PL signal is identical, i.e. a pulse changing from the ‘0’ state to the ‘1’ state during the phase 1 and maintained in the ‘0’ state during the phase 2. Alternatively, when performing a write operation, the phase 2 can be implemented before the phase 1.

In a particular configuration, the memory circuit 100 is configured to apply, for each of the columns of the memory cells 102, a same electrical potential to the bit lines 112A, 112B and to the plate line 106 of said column of memory cells 102 during a precharge phase implemented between two read and/or write operations. This electrical potential equality between the bit lines 112A, 112B and the plate lines 106 can be ensured by transmission gates (or “pass gates”) such as those previously described for the interconnection circuit 120 in FIG. 5. This same potential will be the ground in the example as described. The precharge phases are not shown on the signals in FIG. 4.

In order to prevent the appearance of address conflicts during a dual access to memory cells 102 belonging to different rows and different groups of columns, the memory circuit 100 is configured to apply, during such a multiple read and/or write access, to the bit lines 112A, 112B coupled to the access transistors 108A, 108B set to the on state of the other memory cells 102 belonging to a same rows and columns as the first and second memory cells 102, bias electrical potentials of the same values as those applied to the plate lines 106 coupled to the memory elements 104 of the first and second memory cells 102. Thus, the memory cells 102 not subjected to a read and/or write access but located on the same rows and columns as the memory cells 102 subjected to such an access are thereby protected from unwanted reading or writing.

More generally, to prevent such address conflicts, during a dual read and/or write access to first and second memory cells belonging to different groups of columns of memory cells, the memory circuit 100 is configured to apply, to bit lines 108A, 108B coupled to access transistors of unselected memory cells and set to the on state, electrical potentials of the same values as those applied to the plate lines 106 coupled to the memory elements of the unselected memory cells.

By way of illustration, considering the memory cells 102.1-102.4 shown in FIG. 1, a write operation of a ‘0’ state in the memory cell 102.1 implemented simultaneously with a write operation of a ‘1’ state in the memory cell 102.4 is described below. The values of the potentials applied to the word lines 110A, 110B, the bit lines 112A, 112B and the plate lines 106 of these memory cells 102.1-102.4 are shown in the diagram in FIG. 8.

With such a biasing of the plate lines 106, the word lines 110A, 110B and the bit lines 112A, 112B, the voltage VGS of one of the access transistors 108A, 108B of each of the memory cells 102.1 and 102.4 is greater than the threshold voltage Vt of these access transistors 108A, 108B and their voltage VDS becomes greater than the difference (VGS−Vt). Currents then flow in these transistors, represented by arrows in FIG. 8, causing a ‘0’ state to be written in the memory cell 102.1 and a ‘1’ state to be written in the memory cell 102.4.

To prevent a ‘1’ state from being written in the memory cell 102.2, the potential of the bit line 112A coupled to the access transistor 108A set to the on state of the memory cell 102.2 is defined as being equal to that of the plate line 106 coupled to the memory cell 102.2, i.e. set to the ‘0’ state. Similarly, to prevent a ‘0’ state from being written in the memory cell 102.3, the potential of the bit line 112B coupled to the access transistor 108B set to the on state of the memory cell 102.3 is defined as being equal to that of the plate line 106 coupled to the memory cell 102.3, i.e. set to the ‘1’ state. By applying such potentials, the voltages VDS of the access transistors 108A, 108B which are set to the on state of the memory cells 102 located in the same rows and columns as the memory cells 102 being read and/or written to are maintained at 0 V, thus preventing writing in these memory cells 102.

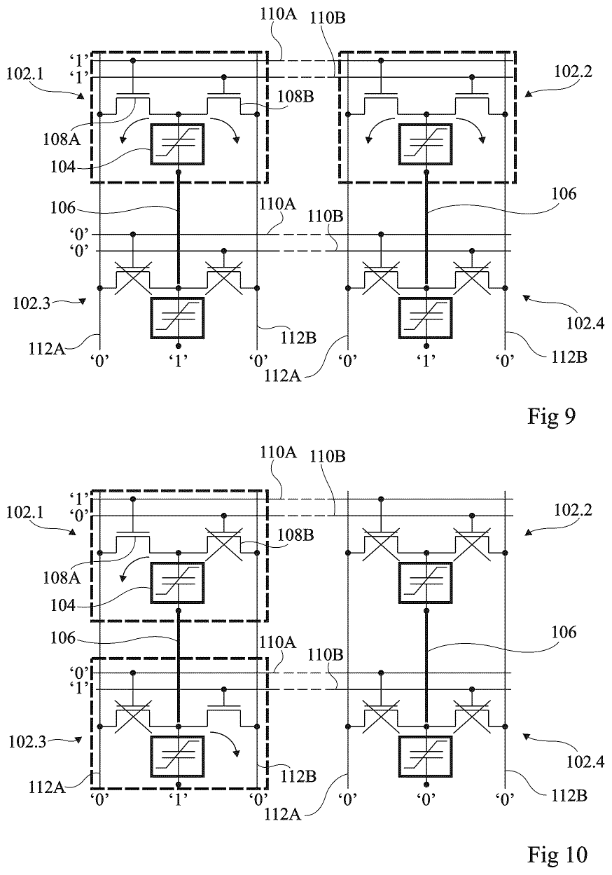

In general, the memory circuit 100 can operate in different configurations to perform simultaneous accesses to two memory cells 102 belonging to different groups of columns. Thus, when the first and second memory cells 102 belong to a same row of memory cells 102, electrical potentials of the same values can be applied to the first and second bit lines 112A, 112B coupled to the access transistors 108A, 108B of the memory cells 102 of columns of memory cells 102 other than those to which the first and second memory cells belong. Such a configuration is shown schematically in FIG. 9, which shows examples of electrical potentials applied to the word lines 110A, 110B, the bit lines 112A, 112B and the plate lines 106, for columns including the selected cells. The other columns (not shown) are such that their bit lines 112A, 112B and their plate lines 106 are all at the same potential, for example equal to the precharge potential equal to “0”.

More generally, when the first and second memory cells being accessed belong to a same row of memory cells, the memory circuit 100 is configured to apply electrical potentials of the same values to the plate lines 106 and the first and second bit lines 112A, 112B coupled to the access transistors 108A, 108B of memory cells belonging to columns other than those to which the first and second memory cells belong.

When accessing two memory cells 102 belonging to a same row of memory cells, as in the example previously described in connection with FIG. 9, the two access transistors 108A, 108B of the two memory cells 102 being accessed can be turned on and the access is then achieved, for a first of the two memory cells 102, via the bit line 112A coupled to this first memory cell 102 and for a second of the two memory cells 102, via the bit line 112B coupled to this second memory cell 102.

Nevertheless, it should be noted that in this access to two cells on the same line, the two access transistors connected to each cell are in the on state. This can cause problems in the case of reading. If the sense amplifier used is connected to a single bit line, it must be ensured that the other bit line does not interfere with the read operation due to its bias and does not interfere with the read device used. In addition, the charges from the memory cell during reading will be distributed between the bit lines. In order to always be able to read a memory cell correctly with a read circuit such as the one shown in FIG. 7, its reference potential Vref will be adjusted and/or it will be possible to provide an amplifier 146 with higher gain and/or a longer read time.

Alternatively, and to avoid the above-indicated drawbacks, for such an access to two memory cells 102 belonging to a same row of memory cells, during a read operation, it is possible to turn on either the access transistors 108A of the two memory cells 102 by setting the first word line 110A coupled to these memory cells 102 to the ‘1’ state and by setting the second word line 110B to the ‘0’ state, or the access transistors 108B of the two memory cells 102 by setting the second word line 110B coupled to these memory cells 102 to the ‘1’ state and by setting the first word line 110A to the ‘0’ state. In this case, to prevent the charge resulting from different information stored in two memory cells 102 being accessed from ending up at the input of a same sense amplifier, it is necessary that each memory cell which is read can be connected to a single sense amplifier 124. In the event that the same sense amplifier 124 is connected to several columns of the same column group, then it is necessary that the selected cells on the same row belong to different column groups.

In addition, the interconnection circuits 120 may be equipped with devices, such as transmission gates, configured to divert the charge from the bit lines 112A to the bit lines 112B and/or from the bit lines 112B to the bit lines 112A. Alternately, the interconnection circuits 120 may be equipped with devices, such as transmission gates, configured to divert the charge from the bit lines 112A to the second common bit line 140 and/or from the bit lines 112B to the first common bit line 138.

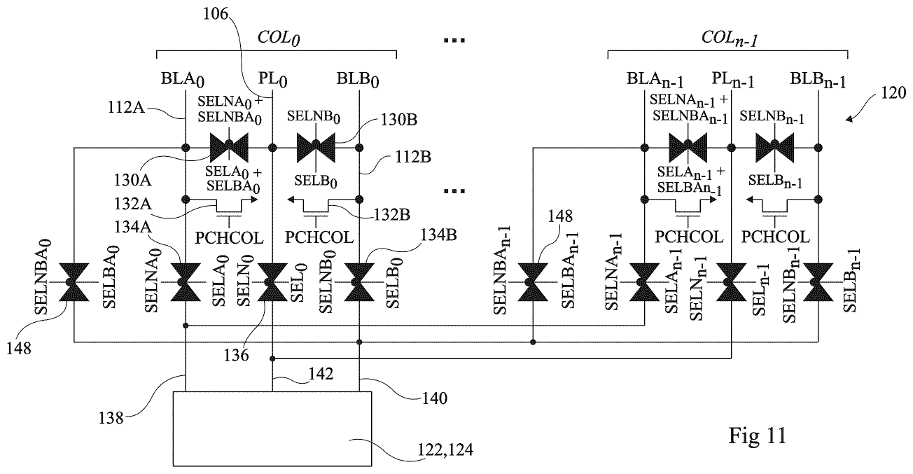

FIG. 11 schematically illustrates an example of such an interconnection circuit 120. In this example, in addition to the elements of the circuit 120 previously described in connection with FIG. 5, this circuit 120 also includes third transmission gates 148, for example of the CMOS type, each comprising an input coupled to a first of the bit lines 112A, 112B of a column of memory cells 102 and an output coupled to the second common bit line 140 of the group of columns of memory cells 102. In the example shown in FIG. 11, for each column of memory cells 102, each of the third transmission gates 148 is configured to divert the charge transmitted on the bit line 112A to the second common bit line 140. In addition, the control signals for these third transmission gates 148 are also applied to the control inputs of the first transmission gates 130A. Thus, when accessing two memory cells 102 belonging to a same row of memory cells 102, the access transistor 108A of each of the two memory cells 102 being accessed is turned on, and the third transmission gate 148 associated with one of the two columns of memory cells 102 to which these two memory cells 102 belong is turned on in order to divert the charge from the bit line 112A associated with this column of memory cells 102 to the second common bit line 140 associated with this column of memory cells 102.

Alternatively, for each column of memory cells 102, each of the third transmission gates 148 may be configured to divert the charge transmitted on the bit line 112B to the first common bit line 138. In this case, when accessing two memory cells 102 belonging to a same row of memory cells, the access transistor 108B of each of the two memory cells 102 is turned on, and the third transmission gate 148 associated with one of the two columns of memory cells 102 to which these two memory cells 102 belong is turned on in order to divert the charge from the bit line 112B associated with this column of memory cells 102 to the first common bit line 138 associated with this group of columns of memory cells 102.

Whatever the bit line to which the read charge is diverted, the control signals of the third transmission gates 148 can be managed by an address arbitration circuit, not shown in FIG. 11, which can also manage the non-activation of the desired word line 110A or 110B coupled to the memory cells 102 being read.

The use of the third transmission gates 148 allows a simultaneous access to memory cells 102 arranged on a same row by ensuring that the selected bit line is ultimately connected to a read circuit.

Alternatively, devices other than transmission gates 148 may be used to divert the charge from one of the bit lines 112A, 112B to the other, or from one of the bit lines 112A, 112B to the second or first common bit line 140, 138, respectively.

As previously indicated, each group of columns of memory cells 102 may be coupled to two sense amplifiers 124 to read two different memory cells 102 located in a same column of memory cells 102, thereby using two different word lines 110 coupled to a same group of columns of memory cells 102, the data being read on each of the first and second bit lines 112A, 112B of this column of memory cells 102. Such a configuration is shown schematically in FIG. 10, which shows examples of electrical potentials applied to the word lines 110A, 110B, the bit lines 112A, 112B and the plate lines 106.

Alternatively, it is possible to perform any type of operation (read and/or write) simultaneously within two memory cells belonging to a same group of columns. In this case, the interconnection circuits 120 are such that the potentials applied to each of the bit lines 112A, 112B of the different columns within a same group of columns can be controlled independently of each other, and several read circuits can be provided to perform parallel reads, as can programming circuits.

In the various exemplary designs, for the columns of memory cells 102 that are not accessed, the potentials applied to the bit lines 112A, 112B of each of these columns of memory cells 102 are equal to that applied to the plate line 106 of this column of memory cells 102 in order to prevent any access to these columns of memory cells 102, and thus preserve memorized values.

In the various exemplary designs as described above, the values of the electrical potentials applied to the bit lines 112A, 112B and the plate lines 106 are indicated while considering a connection direction of the electrodes of the memory elements 104 to the access transistors 108A, 108B and to the plate lines 106. Alternatively, similar operations can be performed for memory elements 104 for which the connection direction is reversed with respect to the examples as described above, by applying complementary electrical potentials (high state when a low state is described, and low state when a high state is described) to the bit lines 112A, 112B and the plate lines 106 relative to the examples as described above.

In an exemplary design of the memory circuit 100, each of the dual-port memory cells 102 can occupy a semiconductor surface area substantially equal to that of a 1T1C memory cell, i.e. a single-port cell. In fact, in a 1T1C memory cell, the gate of the single transistor is generally made in the form of two separate fingers, for reasons of integration and continuity of the active area throughout a memory array, particularly in sub-22 nm technology. In order not to occupy a larger semiconductor surface area, in each of the memory cells 102, which are of the 2T1C type, each of the access transistors 108 may comprise a gate made in the form of a single finger. For example, in 22 nm technology, a memory cell 102 may occupy a semiconductor surface area with a width of 400 nm and a height of 250 nm, i.e. a surface area of 0.1 μm².

In an exemplary design of the memory circuit 100, the word lines 110A and 110B include electrically conductive portions of polysilicon extending into a FEOL (Front-End Of Line) portion of the integrated circuit forming the memory circuit 100. In order to minimize the propagation time of the electrical signals in the word lines 110A, 110B, it is possible to couple, at regular intervals, these polysilicon portions to other conductive portions located in a higher metal level belonging to the BEOL (Back-End Of Line) of the integrated circuit, for example in the metal level 2. Advantageously, these connections between the polysilicon portions and the conductive portions located in a higher metal level are made by spacing these connections from each other such that at least 16 memory cells 102 are interposed between two neighboring connections and, for example, such that at most 256 memory cells 102 are interposed between two neighboring connections, which minimizes the propagation time of the signals in the word lines 110 while limiting the semiconductor surface area occupied by these connections.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A dual-access memory circuit, comprising at least:
memory cells of the FeRAM type arranged in rows and columns, each memory cell comprising at least one memory element a first electrode of which is coupled to a plate line common to a column of memory cells, and at least one first and one second access transistors each coupled to one of first and second bit lines common to said column of memory cells and having a gate coupled to one of first and second word lines common to a row of memory cells;
sense amplifiers and write drive circuits;
interconnection circuits each configured to couple the first and second bit lines and the plate lines of at least one column of memory cells to one of the write drive circuits and to at least one of the sense amplifiers;
wherein, during a dual read and/or write access to first and second selected memory cells belonging to different columns of memory cells and different rows of memory cells, the memory circuit is configured to apply, to bit lines coupled to access transistors set to the on state and of other memory cells belonging to the same columns of memory cells than the first and second selected memory cells, electrical potentials of the same values as those applied to the plate lines coupled to the memory elements of the first and second selected memory cells, and
wherein, during a dual read and/or write access to first and second selected memory cells, the memory circuit is configured to apply, to the bit lines coupled to the access transistors set in the on state and of unselected memory cells belonging to columns other than those to which the first and second selected memory cells belong, electrical potentials of the same values as those applied to the plate lines coupled to the memory elements of these unselected memory cells.

2. The memory circuit according to claim 1, in which the interconnection circuits are each configured to couple the first and second bit lines and the plate lines of a group of memory cell columns to a shared write driver circuit and to a single shared sense amplifier or to two shared sense amplifiers connected respectively to the first and second bit lines of the group of columns.

3. The memory circuit according to claim 1, wherein the dual access is performed during sequential read and/or write accesses to at least a portion of the memory cells including the first and second memory cells.

4. The memory circuit according to claim 3, configured to apply, during sequential read and/or write accesses to memory cells belonging to at least one same row of memory cells, electrical potentials of constant values to the first and second word lines common to said at least one of the rows of memory cells, throughout the duration of said accesses, so as to maintain in the on state, during the total duration of said accesses, the access transistors to which at least one of the first and second word lines is coupled.

5. The memory circuit according to claim 1, further comprising devices configured to divert charge from one of the first and second bit lines to the other in each of the columns of memory cells, or to divert charge from one of the first and second bit lines to a common bit line.

6. The memory circuit according to claim 5, wherein, when the first and second memory cells belong to a same row of memory cells, the memory circuit is configured to turn on only one of the first and second access transistors of each of the first and second memory cells.

7. The memory circuit according to claim 2, wherein each of the interconnection circuits comprises first inputs coupled to the first bit lines of a group of columns of memory cells, second inputs coupled to the second bit lines of the group of columns of memory cells, third inputs coupled to the plate lines of the group of columns of memory cells, a first output configured to be coupled to at least one of the first inputs, a second output configured to be coupled to at least one of the second inputs and a third output configured to be coupled to at least one of the third inputs.

8. The memory circuit according to claim 1, wherein:
during a read operation of one of the memory cells, the memory circuit is configured to apply to one of the first and second bit lines coupled to said memory cell a first state and then a floating electrical potential, and to apply to the plate line coupled to said memory cell a second state different from the first state;
during a write operation of the first state in one of the memory cells, the memory circuit is configured to apply the first state to one of the first and second bit lines coupled to said memory cell, and to apply the second state to the plate line coupled to said memory cell;
during a write operation of the second state in one of the memory cells, the memory circuit is configured to apply the second state to one of the first and second bit lines coupled to said memory cell, and to apply the first state to the plate line coupled to said memory cell.

9. The memory circuit according to claim 1, configured to apply, for each of the columns of memory cells, a same electrical potential to the first and second bit lines and the plate line of said column of memory cells during a precharge phase implemented at the beginning or end of a cycle of operations comprising read operation.

10. The memory circuit according to claim 1, wherein the memory cells are configured to store words in the memory cells such that the bits of each word are stored in several groups of columns of memory cells.

11. The memory circuit according to claim 1, wherein each of several groups of columns of memory cells is coupled to two sense amplifiers, and wherein the memory circuit is configured to implement a dual read access in first and second memory cells belonging to a same column of memory cells.

12. The memory circuit according to claim 1, wherein all interconnection circuits are controlled by a same control circuit.

13. The memory circuit according to claim 1, wherein the gate of each access transistor of each memory cell comprises a single electrically conductive portion.

14. The memory circuit according to claim 1, wherein the word lines comprise polysilicon portions extending in a start-of-line portion of an integrated circuit and metal portions extending in an end-of-line portion of the integrated circuit.

15. A method for making a dual-access memory circuit, comprising at least:
providing memory cells of the FeRAM type arranged in rows and columns, each memory cell comprising at least one memory element a first electrode of which is coupled to a plate line common to a column of memory cells, and at least one first and one second access transistors, each coupled to one of first and second bit lines common to said column of memory cells and having a gate coupled to one of first and second word lines common to a row of memory cells;
providing sense amplifiers and write drive circuits;
providing interconnection circuits each configured to couple the first and second bit lines and the plate lines of at least one column of memory cells to one of the write drive circuits and to at least one of the sense amplifiers;
wherein, during a dual read and/or write access to selected first and second memory cells belonging to different columns of memory cells and different rows of memory cells, the memory circuit is configured to apply, to bit lines coupled to access transistors set to the on state and of other memory cells belonging to the same columns of memory cells than the selected first and second memory cells, electrical potentials of the same values as those applied to the plate lines coupled to the memory elements of the selected first and second memory cells, and
wherein, during a dual read and/or write access to first and second selected memory cells, the memory circuit is configured to apply, to the bit lines coupled to the access transistors set in the on state and of unselected memory cells belonging to columns other than those to which the first and second selected memory cells belong, electrical potentials of the same values as those applied to the plate lines coupled to the memory elements of these unselected memory cells.

16. The method according to claim 15, wherein the memory circuit is implemented in the form of an integrated circuit, and comprising the implementation of polysilicon portions extending in a start-of-line portion of the integrated circuit and metal portions extending in an end-of-line portion of the integrated circuit, which together form the word lines.

17. A method for controlling memory cells of a memory circuit comprising at least:
memory cells of the FeRAM type arranged in rows and columns, each memory cell comprising at least one memory element a first electrode of which is coupled to a plate line common to a column of memory cells, and at least one first and one second access transistors each coupled to one of first and second bit lines common to said column of memory cells and having a gate coupled to one of first and second word lines common to a row of memory cells;
sense amplifiers and write drive circuits;
interconnection circuits each configured to couple the first and second bit lines and the plate lines of at least one column of memory cells to one of the write drive circuits and to at least one of the sense amplifiers;
and wherein, during a dual read and/or write access to first and second selected memory cells belonging to different columns of memory cells and different rows of memory cells, the method comprises applying, to bit lines coupled to access transistors set to the on state and of other memory cells belonging to the same columns of memory cells than the first and second selected memory cells, electrical potentials of the same values as those applied to the plate lines coupled to the memory elements of the first and second selected memory cells, and
wherein, during a dual read and/or write access to first and second selected memory cells, the method comprises applying, to the bit lines coupled to the access transistors set in the on state and of unselected memory cells belonging to columns other than those to which the first and second selected memory cells belong, electrical potentials of the same values as those applied to the plate lines coupled to the memory elements of these unselected memory cells.

18. The method according to claim 17, further comprising:
during a read operation of one of the memory cells, applying a high state to one of the first and second word lines coupled to said memory cell, and applying, to one of the first and second bit lines coupled to said memory cell, a low state and then a floating electrical potential, and applying, to the plate line coupled to said memory cell, a low state and then a high state;
during a write operation of a low state in one of the memory cells, applying a high state to one of the first and second word lines coupled to said memory cell, and applying, to one of the first and second bit lines coupled to said memory cell, a low state, and applying, to the plate line coupled to said memory cell, a high state;
during a write operation of a high state in one of the memory cells, applying a high state to one of the first and second word lines coupled to said memory cell, and applying, to one of the first and second bit lines coupled to said memory cell, a high state, and applying, to the plate line coupled to said memory cell, a low state.
